(19) United States
(12) Patent Application Publication
(10) Pub. No.: US 2012/0044013 A1
(43) Pub. Date: Feb. 23, 2012

(54) ELECTROSTATIC CAPACITANCE-TYPE INPUT DEVICE

(75) Inventor: Tetsuo MURANAKA, Miyagi-ken (JP)

(73) Assignee: ALPS ELECTRIC CO., LTD., Tokyo (JP)

(21) Appl. No.: 13/180,403

(22) Filed: Jul. 11, 2011

(30) Foreign Application Priority Data
Aug. 20, 2010 (JP) 2010-185178

(51) Int. Cl. H03K 17/945

(52) U.S. Cl. 327/517

(57) ABSTRACT

An electrostatic capacitance-type input device includes X driving electrodes and Y driving electrodes on an operation face operated by a finger. A correction electrode and a correction detection electrode are provided to be opposed at a place which is not affected by the finger operating the operation face. Driving voltage is sequentially applied to the X driving electrodes by an X driving unit, and the voltage is also applied to the correction electrode. An input detection signal for detecting a contact position of the finger and a correction detection signal obtained from the correction detection electrode changed on the basis of environmental changes are detected by the same detection unit, and the correction detection signal and the input detection signal are corrected in a data processing unit.

### CLAIM OF PRIORITY

This application claims benefit of Japanese Patent Application No. 2010-185178 filed on Aug. 20, 2010, which is hereby incorporated by reference.

### BACKGROUND OF THE INVENTION

1. Field of the Invention

The present invention relates to an electrostatic capacitance-type input device which obtains an input detection signal according to electrostatic capacitance between a finger and a driving electrode when the input device is operated by the finger of a user, and more particularly, to an electrostatic capacitance-type input device in which a correction electrode is provided at a position where there is the influence from the finger, to correct a change in the electrostatic capacitance caused by environmental changes.

2. Description of the Related Art

The electrostatic capacitance-type input device is provided with a plurality of driving electrodes. When a finger, which is a conductor close to ground potential, of a user approaches the driving electrode to form electrostatic capacitance between the finger and the driving electrode, electric current flowing when applying a driving voltage to the driving electrode is changed, or a delay occurs in the rising edge of voltage. It is possible to recognize an operation using the finger by detecting such change.

The electrostatic capacitance formed between the finger and the driving electrode is a small value, and thus the electrostatic capacitance-type input device has a problem in that erroneous operations easily occur due to environmental changes caused by external noise or an increase in temperature or humidity.

An electrostatic capacitance-type proximity sensor described in Japanese Unexamined Patent Application Publication No. 2006-177838 is provided with a sensor unit having a detection electrode, a detection circuit outputting a detection signal based on the electrostatic capacitance between the detection electrode and the finger, and a subtraction circuit subtracting a subtraction voltage obtained from a subtraction voltage generating circuit from the detection signal, correcting the result, and then outputting a detection signal. A change in the detection signal caused by a change in temperature or humidity is offset by the subtraction process.

An input device described in Japanese Unexamined Patent Application Publication No. 2007-13432 is provided with an input electrostatic sensor in which an operation unit is provided with a plurality of input electrodes. When a finger approaches the input electrode, a delay occurs in the rising edge of the driving voltage received in a pulse shape due to the influence of electrostatic capacitance formed between the input electrode and the finger. It is possible to identify the input electrode approached by the finger, by detecting the delay of the rising edge. A noise detecting electrostatic sensor is provided in an area which is not affected by the finger, to correct the detection output of the input electrostatic sensor with the external noise detected by the noise detecting electrostatic sensor.

### SUMMARY OF THE INVENTION

In the electrostatic capacitance-type proximity sensor described in Japanese Unexamined Patent Application Publication No. 2006-177838, the subtraction voltage for correcting the detection signal obtained from the sensor unit is generated by the subtraction voltage generating circuit. The subtraction voltage generating circuit is formed of a volume or DA converter. Alternatively, the subtraction voltage is generated by the subtraction voltage circuit using a detection value of a temperature and humidity sensor.

Since the subtraction voltage generated by the subtraction voltage generating circuit does not directly relate to the noise overlapped with the detection signal from the sensor unit, it is difficult to accurately associate the subtraction voltage with change in usage environment of the sensor unit, and it is difficult to expect correction with high precision.

The input device described in Japanese Unexamined Patent Application Publication No. 2007-13432 detects the noise using the noise detecting electrode provided together with the input electrode to correct the detection output of the input electrostatic sensor. However, the input electrostatic sensor and the noise detecting electrostatic sensor are driven by different circuits, and thus the configuration of the circuit is complicated.

Since the cycle of a clock signal for applying voltage to the input electrode and the cycle of a clock signal for applying voltage to the noise detecting electrode are different from each other, it is difficult to detect a noise component overlapped with the detection output of the input electrostatic sensor and a noise component overlapped with the noise detecting electrostatic sensor under the same condition. For this reason, there is a case where additional correction is necessary to remove the noise of the detection signal.

The present invention provides an electrostatic capacitance-type input device to correct change in an input detection signal based on environmental changes with little circuit burden.

In addition, the present invention provides an electrostatic capacitance-type input device capable of obtaining an input detection signal obtainable by applying a driving voltage to a driving electrode and a correction detection signal obtainable by applying a driving voltage to a correction electrode under the same condition, and capable of raising the precision in correcting the input detection signal.

According to an aspect of the invention, there is provided an electrostatic capacitance-type input device having a plurality of driving electrodes in which electrostatic capacitance is formed between an operation face operated by the finger of a user and the finger coming in contact with the operation face, wherein a driving voltage is applied to each driving electrode, and voltage change or current change when the finger approaches the driving electrode to which the driving voltage is applied is detected as an input detection signal, including: a correction electrode that is provided at a position away from the operation face; a common driving unit that applies a driving voltage to both of the driving electrode and the correction electrode; and a common detection unit that detects both of a correction detection signal that is a voltage change or a current change when the driving voltage is applied to the correction electrode, and the input detection signal, wherein the input detection signal is corrected on the basis of the correction detection signal.

In the input device of the aspect of the invention, the driving voltage is applied from the common driving unit to the driving electrode and the correction electrode, and the input detection signal and the correction detection signal are detected in the common detection unit. It is possible to simplify the circuit configuration using the common driving unit and the common detection unit.

In the input device, it is preferable that a driving voltage with the same time length is applied from the driving unit to each driving electrode and the correction electrode. More preferably, a driving voltage with the same time length is sequentially applied in the same cycle from the driving unit to each driving electrode and the correction electrode.

When a driving voltage with the same time length is applied to the driving electrode and the correction electrode, it is possible to perform a detection operation based on the driving electrode and a detection operation based on the correction electrode under the approximated condition, and it is possible to correct the input detection signal with high precision by the correction detection signal obtainable by driving the correction electrode.

In the input device, it is preferable that a plurality of driving electrodes and a plurality of detection electrodes at an interval from the driving electrodes are provided on the operation face, a correction detection electrode opposed to the correction electrode is provided, the detection electrode and the correction detection electrode are connected to each other, the input detection signal is obtained from the detection electrode when the driving voltage is applied to the plurality of driving electrodes, and the correction detection signal is obtained from the correction detection electrode when the driving voltage is applied to the correction electrode.

In this case, it is preferable that the electrostatic capacitance formed between one detection electrode and the driving electrode adjacent thereto and the electrostatic capacitance between the correction electrode and the correction detection electrode are substantially the same.

When the electrostatic capacitances are the same as described above, it is possible to obtain the correction detection signal under the condition approximated to the input detection signal, and it is possible to correct the input detection signal with high precision by the correction detection signal.

The input device may further include a plurality of X electrodes arranged in parallel to each other and a plurality of Y electrodes arranged in parallel to each other in a direction perpendicular to the X electrodes, wherein one side of the X electrodes and the Y electrodes serves as the driving electrode and the other side serves as the detection electrode when the driving voltage is applied, and the driving voltage is applied to the correction electrode with any one side of the X electrodes and the Y electrodes.

In the input device, a plurality of driving electrodes with the same area are arranged on the operation face, the correction electrode is formed with the same area as that of the driving electrode, the driving voltage is applied from the driving unit to the driving electrode and the correction electrode, an input detection signal is obtained from each driving electrode, and a correction detection signal is obtained from the correction electrode.

In the configuration, the correction electrode and the driving electrode are formed with the same area, it is possible to obtain the correction detection signal under the condition approximated to the input detection signal, and it is possible to correct the input detection signal with high precision by the correction detection signal.

According to the invention, the driving unit driving the driving electrode and the correction electrode is common, the input detection signal and the correction detection signal are detected in the common detection unit, thus it is possible to simplify the circuit configuration, and it is possible to control the input detection and the correction detection using the common IC.

It is possible to detect the input detection signal and the correction detection signal under the approximated condition, and it is possible to raise the precision in correction of the input detection signal.

### BRIEF DESCRIPTION OF THE DRAWINGS

FIG. 1 is a diagram illustrating an electrostatic capacitance-type input device of a first embodiment of the invention.

FIG. 2A and FIG. 2B are diagrams illustrating a detection output of the input device shown in FIG. 1 with change in current.

FIG. 3 is a diagram illustrating an electrostatic capacitance-type input device of a second embodiment of the invention.

FIG. 4 is a diagram illustrating an electrostatic capacitance-type input device of a third embodiment of the invention.

FIG. 5 is a diagram illustrating a circuit configuration of a driving and detecting unit of the input device shown in FIG. 4.

FIG. 6A and FIG. 6B are diagrams illustrating detection outputs of the input devices shown in FIG. 4 and FIG. 5, with change in voltage.

FIG. 7A to FIG. 7C are diagrams illustrating an example of an input detection signal and a correction detection signal.

FIG. 8A to FIG. 8C are diagrams illustrating an example of an input detection signal and a correction detection signal.

FIG. 9 is a diagram illustrating a structure in which the input device is provided in a case.

FIG. 10 is a diagram illustrating a structure in which the input device is provided in a case.

### DESCRIPTION OF THE PREFERRED EMBODIMENTS

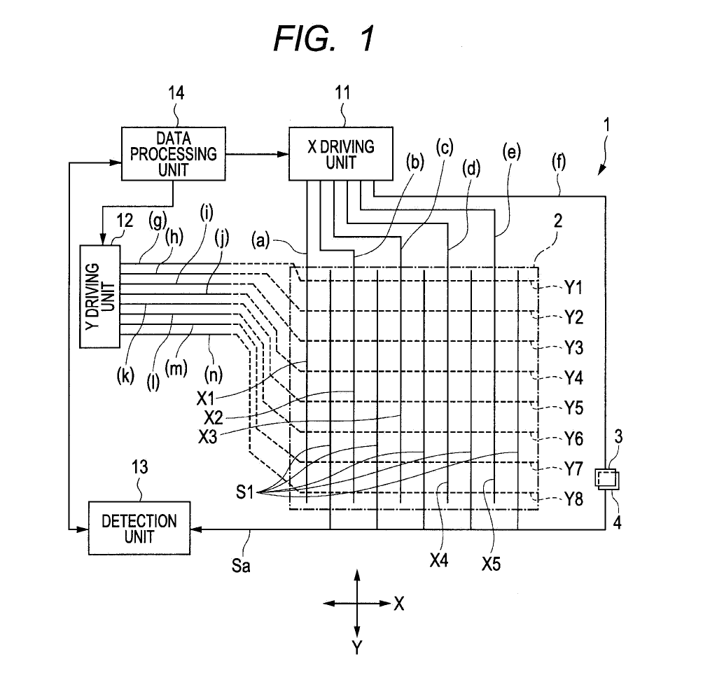

An electrostatic capacitance-type input device 1 of a first embodiment shown in FIG. 1 has an operation face 2 having a regular area. The operation face 2 is covered with a surface layer formed of relatively thin synthetic resin, and an electrode is formed thereunder. A thickness of the surface layer is set to form detectable electrostatic capacitance between the finger of a user coming in contact with the surface of the operation face 2 and the electrode.

X driving electrodes X1, X2, X3, X4, and X5 are provided under the surface layer of the operation face 2. The X driving electrodes X1 to X5 are linearly arranged in the Y direction, and are provided in parallel at a regular interval in the X direction. A plurality of Y driving electrodes Y1, Y2, Y3, Y4, Y5, Y6, Y7, and Y8 are provided under the same operation face 2. The Y driving electrodes Y1 to Y8 are linearly arranged in the X direction, and are provided in parallel at a regular interval in the Y direction. The X driving electrodes X1 to X5 and the Y driving electrodes Y1 to Y8 are perpendicular to each other. The X driving electrodes and the Y driving electrodes may be overlapped through a thin insulating layer, and the X driving electrodes X1 to X5 and the Y driving electrodes Y1 to Y8 are insulated from each other.

A plurality of detection electrodes S1 are formed on the face where the X driving electrodes X1 to X5 are formed. The plurality of detection electrodes S1 are linearly arranged in the Y direction between the X driving electrodes adjacent to each other. The detection electrodes S1 are provided in parallel at a regular interval in the X direction. The detection electrodes S1 are parallel to the X driving electrodes X1 to X5, and are provided at a uniform distance from the X driving electrodes X1 to X5. The detection electrodes S1 may be provided between the Y driving electrodes adjacent to each other on the face where the Y driving electrodes Y1 to Y8 are formed.

The X driving electrodes X1 to X5, the Y driving electrode Y1 to Y8, and the detection electrodes S1 are formed of a low-resistance conductive material such as gold, silver, and copper. In an apparatus in which a color liquid crystal panel and the like are provided on the inside of the operation face 2, layers forming the operation face 2 are transparent, and the X driving electrodes X1 to X5, the Y driving electrodes Y1 to Y8, and the detection electrodes S1 are formed of a transparent electrode material such as ITO.

In the input device 1 shown in FIG. 1, a correction electrode 3 and a correction detection electrode 4 are provided to be opposed at a position away from the operation face 2, that is, at a part where it is substantially difficult to form electrostatic capacitance between the finger of the user coming in contact with the operation face 2 and the electrode.

The input device 1 has an X driving unit 11. The X driving unit 11 sequentially drives six driving lines (a), (b), (c), (d), (e), and (f). Five driving lines (a), (b), (c), (d), and (e) are connected to the X driving electrodes X1, X2, X3, X4, and X5, respectively, and one driving line (f) is connected to the correction electrode 3. Accordingly, the driving voltage is sequentially applied from the X driving unit 11 in order of the X driving electrodes X1, X2, X3, X4, and X5, and the correction electrode 3.

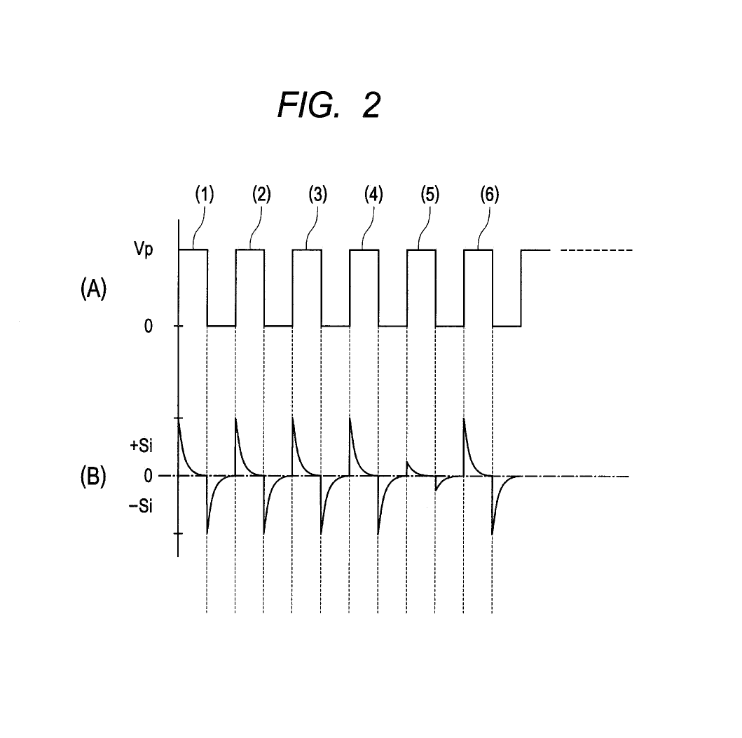

A driving voltage Vp changed as a rectangular wave shown in FIG. 2A is sequentially applied to the driving lines (a), (b), (c), (d), (e), and (f). The time lengths of the driving voltages Vp applied to the driving lines are the same, and cycles of the driving voltages Vp applied to the driving lines (a), (b), (c), (d), (e), and (f) are the same. The time length of the driving voltage is 1 ms or less, and the cycle is 2 ms or less.

The input device 1 has a Y driving unit 12. The Y driving unit 12 sequentially drives eight driving lines (g), (h), (i), (j), (k), (l), (m), and (n). The driving lines (g), (h), (i), (j), (k), (l), (m), and (n) are connected to the Y driving electrodes Y1, Y2, Y3, Y4, Y5, Y6, Y7, and Y8, respectively.

A driving voltage Vp changed as a rectangular wave is sequentially applied from the Y driving unit 12 to the driving lines (g), (h), (i), (j), (k), (l), (m), and (n). A time length of the driving voltage applied from the Y driving unit 12 is 1 ms or less, a cycle thereof is 2 ms or less.

In the driving lines (a), (b), (c), (d), (e), and (f) and the driving lines (g), (h), (i), (j), (k), (l), (m), and (n), when the driving voltage Vp is applied to any driving line, the driving voltage Vp is not applied to the other driving lines. For example, the driving voltage Vp is sequentially applied to the driving lines (a), (b), (c), (d), (e), and (f), and subsequently, the driving voltage Vp is sequentially applied to the driving lines (g), (h), (i), (j), (k), (l), (m), and (n), which is repeated. It is preferable that the driving line to which the driving voltage Vp is not applied is converted into ground potential.

As shown in FIG. 1, the plurality of detection electrodes S1 are connected to each other and are collected to a common detection line Sa, and the correction detection electrode 4 is also connected to the detection line Sa. The detection line Sa is connected to the detection unit 13. A detection signal detected by the detection unit 13 may be transmitted to a data processing unit 14. The driving timing of the X driving unit 11 and the Y driving unit 12 is controlled by the data processing unit 14. The X driving unit 11, the Y driving unit 12, the detection unit 13, the data processing unit 14, an A/D conversion unit, and a switching circuit which switches the driving power may be housed in the same IC package.

An operation of the input device 1 shown in FIG. 1 will be described.

The driving voltage Vp changed as the rectangular wave shown in FIG. 2A is sequentially applied from the X driving unit 11 and the Y driving unit 12 to the driving lines (a), (b), . . . , (m), and (n). The driving voltage Vp is applied in order of X driving electrodes X1, X2, X3, X4, and X5, and the correction electrode 3, and then is applied in order of the Y driving electrodes Y1, Y2, Y3, Y4, Y5, Y6, Y7, and Y8.

In FIG. 2A, (1) is a driving voltage applied to the X driving electrode X1, (2) is a driving voltage applied to the X driving electrode X2, and (3) is a driving voltage applied to the X driving electrode X3. In addition, (4) is a driving voltage applied to the X driving electrode X4, (5) is a driving voltage applied to the X driving electrode X5, and (6) is a driving voltage applied to the correction electrode 3. Thereafter, the driving voltage Vp is sequentially applied to the Y driving electrodes Y1, Y2, Y3, . . . .

As shown in FIG. 2A, the magnitude, time length, and cycle of the driving voltage Vp applied to the X driving electrodes X1 to X5, the correction electrode 3, and the Y driving electrodes Y1 to Y8 are the same.

When the driving voltage Vp is sequentially applied to the X driving electrodes X1 to X5, the correction electrode 3, and the Y driving electrodes Y1 to Y8, change in current of the detection line Sa is detected as a detection signal in the detection unit 13 as shown in FIG. 2B.

Electrostatic capacitance is formed between the X driving electrodes X1 to X5 and the detection electrode S1, and electrostatic capacitance is formed between the Y driving electrodes Y1 to Y8 and the detection electrode S1.

Accordingly, as shown in FIG. 2B, when the driving voltage Vp of the rectangular wave is applied to the X driving electrode X1 in (1), positive current +Si flows in the detection electrode S1 at the rising timing, and negative current −Si flows in the detection electrode S1 at the falling timing of the driving voltage Vp applied to the X driving electrode X1. When the finger does not come in contact with the operation face 2 and there is no environmental change or noise, the currents +Si and −Si are regular.

At the timing of (5) shown in FIG. 2A, when the driving voltage Vp is applied to the X driving electrode X5 and the finger comes in contact with the operation face 2 in the vicinity of the X driving electrode X5, a large amount of current flows to the finger at during rising and falling of the driving voltage Vp applied to the X driving electrode X5 and the currents +Si and −Si flowing in the detection line Sa decrease, since the finger of the ground potential is opposed to the X driving electrode X5 in a wide area.

In the detection unit 13, the positive current +Si or the negative current −Si of the detection line Sa is added and smoothed, an input detection signal is obtained, and the input detection signal may be transmitted to the data processing unit 14. In the data processing unit 14, it is possible to detect the position of the operation face 2 coming in contact with the finger, from information of a driving electrode to which the driving voltage Vp is applied, and an input detection signal obtainable from the detection unit 13.

The input device 1 shown in FIG. 1 is provided with the correction electrode 3 and the correction detection electrode 4 at a position which is not affected by the finger coming in contact with the operation face 2. Since the driving voltage Vp is sequentially applied from the X driving unit 11 to the driving lines (a) to (f), the driving voltage Vp is applied to the correction electrode 3 after the X driving electrode X5.

When the driving voltage Vp is applied to the correction electrode 3, the currents +Si and −Si flow in the correction detection electrode 4, and the currents are detected through the detection line Sa by the detection unit 13. In the detection unit 13, absolute values of the currents are added to smooth them, a correction detection signal is obtained, and the correction detection signal may be transmitted to the data processing unit 14.

When the usage environment of the electronic apparatus provided with the input device 1 is changed and thus humidity or temperature changes, the electrostatic capacitance between the correction electrode 3 and the correction detection electrode 4 is changed and the correction detection signal is changed.

When the driving voltage Vp is applied to the driving line (f), the data processing unit 14 monitors the correction detection signal obtainable from the detection unit 13. When the correction detection signal is changed over the range of a preset threshold value, it is determined that the usage environment of the input device 1 is drastically changed and the input detection signal is corrected. In this case, in the correction operation, the change in the correction detection signal is offset from the input detection signal obtainable from the detection unit 13 when the driving voltage Vp is applied to the X driving electrode or the Y driving electrode.

It is preferable that the electrostatic capacitance between the correction electrode 3 and the correction detection electrode 4 be substantially the same as the electrostatic capacitance between one X driving electrode and the detection electrode 51 positioned on both sides thereof, it is preferable to be adjusted to be substantially the same as the electrostatic capacitance between and the other Y driving electrode and the plurality of detection electrodes S1. In the specification, the electrostatic capacitances are substantially the same, which means that columns of a unit are the same, that is, the difference in electrostatic capacitance is 10 times or less. However, it is more preferable that the difference in electrostatic capacitance be 5 times or less.

When the electrostatic capacitances are substantially the same, it is possible to obtain the correction detection signal obtainable from the correction detection electrode 4 and the input detection signal obtainable from the detection electrode S1 under the approximated condition when the usage environment is changed. That is, the change in environment has an influence on an opposed portion of the driving electrode and the detection electrode S1 and an opposed portion of the correction electrode 3 and the correction detection electrode 4, with the same column. For this reason, it is possible to correct the change in the input detection signal caused by the environmental change with high precision using the correction detection signal.

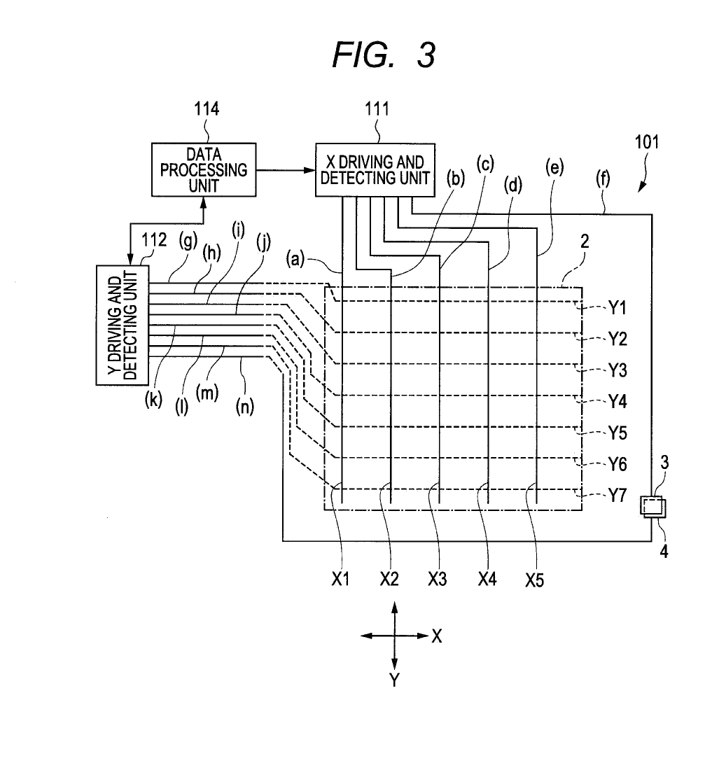

FIG. 3 shows an input device 101 of a second embodiment of the invention.

The operation face 2 of the input device 101 is provided with a plurality of X driving electrodes X1, X2, X3, X4, and X5 and a plurality of Y driving electrodes Y1, Y2, Y3, Y4, Y5, Y6, and Y7 under the surface layer formed of synthetic resin. The X driving electrodes X1 to X5 and the Y driving electrodes Y1 to Y7 are insulated from each other and are perpendicular to each other. The input device 101 shown in FIG. 3 different from the input device 1 shown in FIG. 1 is not provided with the detection electrode S1.

Driving lines (a), (b), (c), (d), and (e) arranged from an X driving and detecting unit 111 are connected to the X driving electrodes X1, X2, X3, X4, and X5, respectively, a driving line (f) arranged from the X driving and detecting unit 111 is connected to the correction electrode 3. Driving lines (g), (h), (i), (j), (k), (l), and (m) arranged from the Y driving and detecting unit 112 are connected to the Y driving electrode Y1, Y2, Y3, Y4, Y5, Y6, and Y7, respectively, and a driving line (n) arranged from the Y driving and detecting unit 112 is connected to the correction detection electrode 4.

The X driving and detecting unit 111 and the Y driving and detecting unit 112 are connected to the data processing unit 114.

In the input device 101 shown in FIG. 3, the driving voltage Vp with the time length shown in FIG. 2A is applied from the X driving and detecting unit 111 to the driving lines (a), (b), (c), (d), (e), and (f) at a regular cycle, and then the driving voltage Vp is sequentially applied from the Y driving and detecting unit 112 to the driving lines (g), (h), (i), (j), (k), (l), and (m). However, the driving voltage Vp is not applied to the driving line (n).

That is, the driving voltage Vp is applied in order of the X driving electrode X1, the X driving electrode X2, the X driving electrode X3, the X driving electrode X4, the X driving electrode X5, and the correction electrode 3, and then the driving voltage Vp is applied in order of the Y driving electrode Y1, the Y driving electrode Y2, the Y driving electrode Y3, the Y driving electrode Y4, the Y driving electrode Y5, the Y driving electrode Y6, and the Y driving electrode Y7, which is repeated.

In the input device 101 shown in FIG. 3, when the driving voltage Vp is sequentially applied from the X driving and detecting unit 111 to the driving lines (a), (b), (c), (d), (e), and (f), the driving lines (g), (h), (i), (j), (k), (l), (m), and (n) function equivalently to the detection line Sa shown in FIG. 1, and the current change of all the driving lines (g) to (n) is detected by the Y driving and detecting unit 112. Meanwhile, when the driving voltage Vp is sequentially applied from the Y driving and detecting unit 112 to the driving lines (g), (h), (i), (j), (k), (l), and (m), the driving lines (a), (b), (c), (d), and (e) function equivalently to the detection line Sa shown in FIG. 1, and the current change of all the driving lines (a) to (e) is detected by the Y driving and detecting unit 112.

When the driving voltage Vp is applied from the X driving and detecting unit 111 to the X driving electrodes X1 to X5, the current change shown in FIG. 2B is detected by the Y driving and detecting unit 112 and an input detection signal is generated. Similarly, when the driving voltage Vp is applied from the Y driving and detecting unit 112 to the Y driving electrodes Y1 to Y7, the current change shown in FIG. 2B is detected by the X driving and detecting unit 111 and an input detection signal is generated. The input detection signals detected by the X driving and detecting unit 111 and the X driving and detecting unit 111 may be transmitted to the data processing unit 114.

In the data processing unit 114, it is possible to detect a position of the operation face 2 coming in contact with the finger, from information of a driving electrode of the X driving electrodes X1 to X5 and the Y driving electrode Y1 to Y7 to which the driving voltage Vp is applied, and the input detection signal.

In the input device 101 shown in FIG. 3, the driving voltage Vp is applied to the correction electrode 3 after the X driving electrodes X1, X2, X3, X4, and X5, the current change in this case is detected by the correction detection electrode 4, and is output as the correction detection signal to the Y driving and detecting unit 112.

When the driving voltage Vp is applied from the X driving and detecting unit 111 to the driving line (f), the data processing unit 114 monitors the correction detection signal based on the current change of the driving line (n) detected by the Y driving and detecting unit 112. When the change amount of the correction detection signal is over a predetermined threshold value, it is determined that the change in the usage environment of the input device 101 is large, and the change in the input detection signal is corrected by the correction detection signal.

In FIG. 3, the driving voltage Vp is applied to the correction electrode 3 after the driving voltage Vp is sequentially applied to the X driving electrodes X1 to X5. However, the driving voltage is not applied to the driving line (n) after the driving voltage Vp is sequentially applied to the Y driving electrodes Y1 to Y7, and the driving voltage Vp is sequentially applied to the X driving electrodes X1 to X5 again. That is, the driving voltage Vp is applied only from the driving line (f) in the correction electrode 3, and the driving line (n) is considered and used only as the detection line.

However, the driving voltage Vp may be applied to the correction detection electrode 4 after the driving voltage Vp is applied to the Y driving electrodes Y1 to Y7, in this case, the driving line (f) may be used as the detection line, the current change may be detected in the X driving and detecting unit 111, and the correction detection signal may be generated.

Also in the input device 101 shown in FIG. 3, it is preferable that the electrostatic capacitance between the correction electrode 3 and the correction detection electrode 4 be substantially the same as the electrostatic capacitance between one X driving electrode (e.g., X1) and all the Y driving electrodes (Y1 to Y7), and is substantially the same as the electrostatic capacitance between one Y driving electrode (e.g., Y1) and all the X driving electrodes (X1 to X5). When the electrostatic capacitances are substantially the same, it is possible to detect a change state of the correction detection signal detected at an opposed portion of the correction electrode 3 and the correction detection electrode 4 and a change state of the input detection signal detected from an opposed portion of the X driving electrode and the Y driving electrode under the approximated condition, and it is possible to raise precision when the input detection signal is corrected by the correction detection signal.

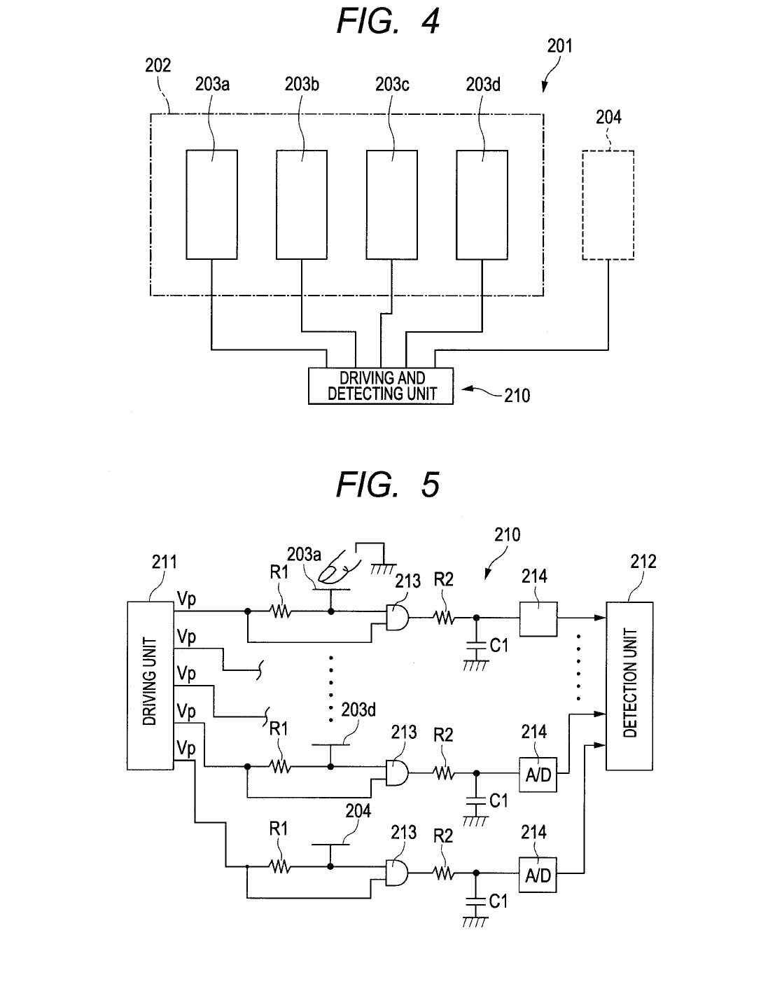

FIG. 4 shows an input device 201 of a third embodiment.

The input device 201 is provided with a plurality of driving electrodes 203a, 203b, 203c, and 203d under the surface layer formed of synthetic resin, on the operation face 202. The driving electrodes 203a, 203b, 203c, and 203d are formed with the same area. A correction electrode 204 is provided in an area which is not substantially affected by the finger coming in contact with the operation face 202. The correction electrode 204 is formed of a conductive material with the same thickness as that of the driving electrodes 203a, 203b, 203c, and 203d, with the same area.

In the plurality of driving electrodes 203a, 203b, 203c, and 203d and the correction electrode 204, the driving voltage Vp is applied and a detection signal is detected from a common driving and detecting unit 210.

FIG. 5 shows a detailed circuit configuration of the driving and detecting unit 210, and FIG. 6A and FIG. 6B show waveforms of the driving voltage Vp and the detection signal.

As shown in FIG. 5, the driving and detecting unit 210 is provided with a driving unit 211, and the driving voltage Vp shown in FIG. 6A is applied from the driving unit 211 to the driving electrodes 203a, 203b, 203c, and 203d, and the correction electrode 204. Similarly to FIG. 2A, the driving voltage Vp is sequentially applied to the driving electrodes 203a, 203b, 203c, and 203d, and the correction electrode 204 with the rectangular wave with the same time length at a regular cycle.

As shown in FIG. 5, a delay circuit is configured by the driving electrodes 203a, 203b, 203c, and 203d, the correction electrode 204, a resistor R1.

When the finger does not approach any of the driving electrodes 203a, 203b, 203c, and 203d, the change in the rising edge of the voltage detected by the delay circuit is a waveform indicated by Sv1 in FIG. 6A. The voltage when the rising waveform Sv1 is over a predetermined threshold value Vs, and the driving voltage Vp are calculated by an AND circuit 213, and it is possible to obtain an addition signal Sp1 shown in FIG. 6A. The addition signal Sp1 is converted into direct-current voltage by a smoothing circuit formed of a resistor R2 and a capacitor C1, is converted into a digital value by an A/D conversion unit 214, and may be transmitted as the input detection signal to the detection unit 212.

When the finger approaches any of the driving electrodes 203a, 203b, 203c, and 203d, high electrostatic capacitance is formed between the driving electrode which the finger approaches and the finger that is the ground potential, the rising edge of the detection voltage passing through the delay circuit formed of the electrostatic capacitance and the resistor R1 is drastically delayed, and the change in the detection voltage is a waveform indicated by Sv2 in FIG. 6B. In this case, when the voltage when the rising waveform Sv2 is over the threshold value Vs, and the driving voltage Vp are calculated by the AND circuit 213, it is possible to obtain an addition signal Sp2. A time length W2 of the addition signal Sp2 shown in FIG. 6B is shorter than a time length W1 of the addition signal Sp1 shown in FIG. 6A. The addition signal Sp2 is converted into direct-current voltage by a smoothing circuit formed of a resistor R2 and a capacitor C1, is converted into a digital value by an A/D conversion unit 214, and may be transmitted as the input detection signal to the detection unit 212.

As described above, when the finger approaches any of the driving electrodes 203a, 203b, 203c, and 203d, the input detection signal obtainable when the driving voltage Vp is applied to the driving electrode which the finger approaches is drastically changed and decreased.

In the driving unit 211, it is possible to detect the driving electrode the finger approaches by sequentially applying the driving voltage Vp to the driving electrodes 203a, 203b, 203c, and 203d and monitoring the change in the input detection signal in the detection unit 212. Alternatively, it is possible to detect the driving electrode the finger approaches by simultaneously applying the driving voltage Vp of a continuous pulse shape to the driving electrodes 203a, 203b, 203c, and 203d, and sequentially replacing and monitoring the input detection signal from the driving electrodes by the detection unit 212.

The driving voltage Vp is applied from the driving electrode 211 to the correction electrode 204. The time length and cycle of the driving voltage Vp are the same as the time length and cycle of the driving voltage Vp which can be transmitted to the driving electrodes 203a, 203b, 203c, and 203d. When the usage environment of the input device 201 is drastically changed, for example, humidity or temperature is drastically raised, the correction detection signal obtainable from the correction electrode 204 is changed. When the change value is over a predetermined threshold value, the input detection signal is corrected using the correction detection signal.

In the input device 201 shown in FIG. 4, since the correction electrode 204 is formed with the same material, the same thickness, and with the same area as those of the driving electrodes 203a to 203d, it is possible to detect the change in the correction detection signal caused by the environmental change in the correction electrode 204 under the same condition as that of the change in the input detection signal from the driving electrodes 203a to 203d, and it is possible to correct the input detection signal with high precision by the correction detection signal.

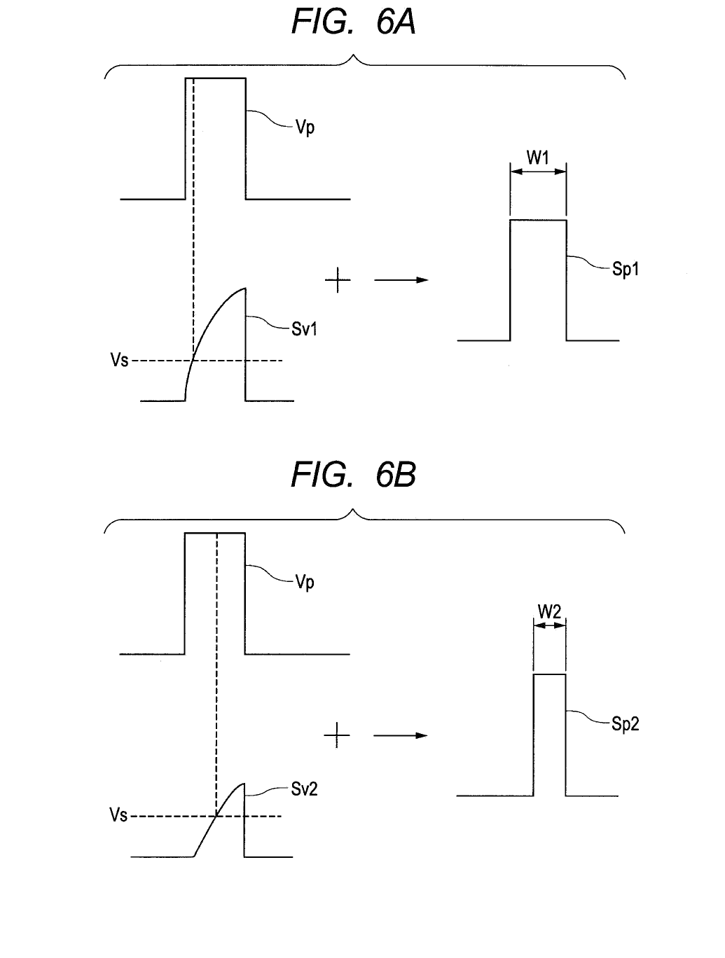

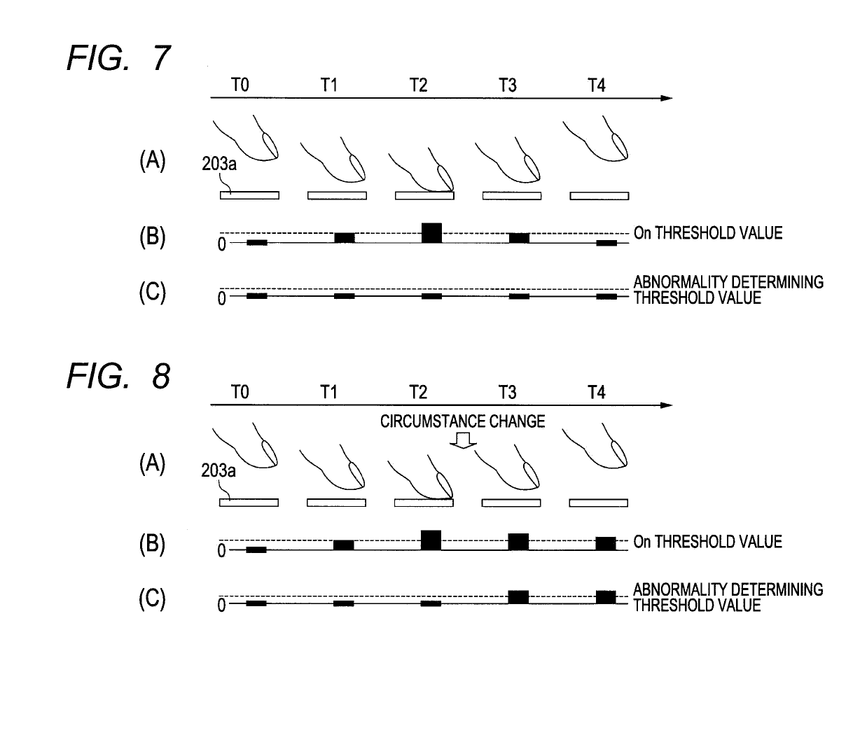

FIG. 7A to FIG. 8C schematically show a relation between the change in the input detection signal and the change in the correction detection signal.

The driving electrode 203a shown in FIG. 7A and FIG. 8A is the same as that provided on the operation face 202 of the input device 201 of the third embodiment shown in FIG. 4 and FIG. 5.

FIG. 7A and FIG. 8A show the change in distance between the driving electrode 203a and the finger with the lapse of time. FIG. 7B and FIG. 8B show the change in the input detection signal when the driving voltage Vp is applied to the driving electrode 203a, and FIG. 7C and FIG. 8C show the change in the correction detection signal when the driving voltage Vp is applied to the correction electrode 204.

FIG. 7A to FIG. 7C shows a state where the usage environment is not drastically changed, and the change width of the correction detection signal shown in FIG. 7C is not over the threshold value. In this case, as shown in FIG. 7B, it is accurately detected that the finger approaches by the input detection signal without abnormal change in the input detection signal for detecting that the finger approaches the driving electrode 203a.

FIG. 8A to FIG. 8C show a state where the usage environment is drastically changed between the time T3 and the time T4, such as rising of humidity and rising of temperature. In this case, as shown in FIG. 8B, the change in the input detection signal is large, it is a state where the same level as the time when the operation electrode 203a is operated by the finger is erroneously detected at the times T3 and T4 although the finger gets away from the driving electrode 203a. However, as shown in FIG. 8C, after the time T3, the correction detection signal detected from the correction electrode 204 is changed over the threshold value according to the change in the usage environment. In the data processing unit, it is possible to prevent the erroneous detection state from occurring by correcting the input detection signal, such as subtracting the correction detection signal in this case from the input detection signal shown in FIG. 8B.

The correction operation using the correction detection signal described above is the same in the input device 1 and the input device 101 shown in FIG. 1 to FIG. 3.

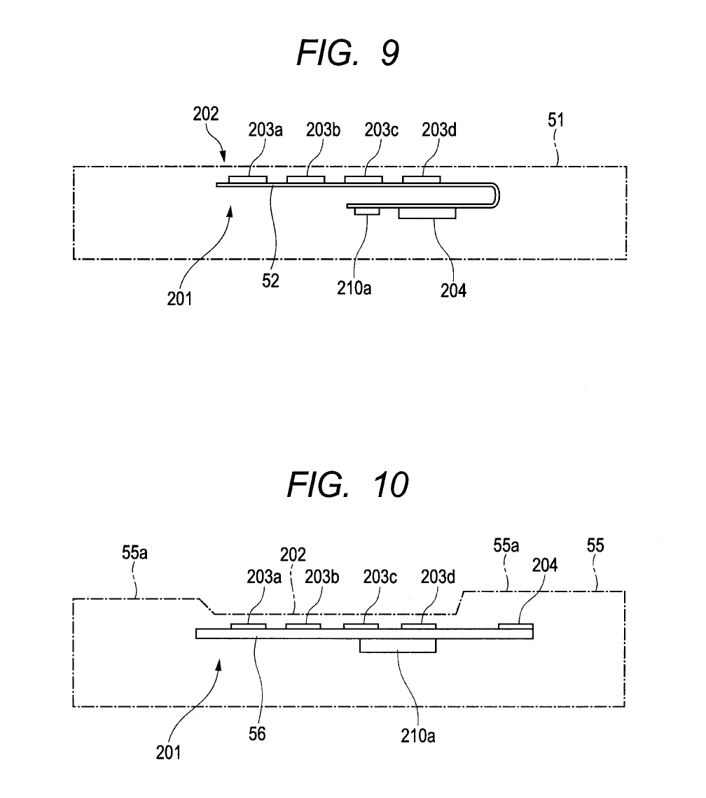

FIG. 9 and FIG. 10 show a state where the input device 201 of the third embodiment is housed in a case of the electronic apparatus.

The surface of the case 51 shown in FIG. 9 is the operation face 202. The driving electrodes 203a, 203b, 203c, and 203d are mounted on a flexible insulating substrate 52, and are provided at a position close to the operation face 202, to detect the finger which approaches the operation face 202 by the driving electrodes 203a, 203b, 203c, and 203d. The insulating substrate 52 may be bent at an angle of about 180° , and the IC 210a provided therein with the correction electrode 204 and the driving and detecting unit 210 is mounted on the bent portion. Accordingly, it is possible to neglect the electrostatic capacitance formed between the finger coming in contact with the operation face 202 and the correction electrode 204.

In a case 55 shown in FIG. 10, a part of a surface 55a thereof is recessed, and a bottom of the recessed portion is the operation face 202. An insulating substrate 56 provided with the driving electrodes 203a, 203b, 203c, and 203d is provided at a position close to the operation face 202, and it is possible to detect the finger which approaches the operation face 202 using any of the driving electrodes 203a, 203b, 203c, and 203d. The correction electrode 204 is provided on the surface of the insulating substrate 56, but is provided at a position deviating from the operation face 202, and the distance between the correction electrode 204 and the surface 55a of the case 55 is long. For this reason, it is possible to neglect the electrostatic capacitance formed between the finger coming in contact with the operation face 202 or the finger coming in contact with the surface 55a and the correction electrode 204.

In addition, the IC 210a is mounted on the back side of the insulating substrate 56.

The input device 1 and the input device 101 shown in FIG. 1 to FIG. 3 are housed in the cases 51 or 55 as shown in FIG. 9 or FIG. 10.

It should be understood by those skilled in the art that various modifications, combinations, sub-combinations and alterations may occur depending on design requirements and other factors insofar as they are within the scope of the appended claims of the equivalents thereof.

What is claimed is:

1. An electrostatic capacitance-type input device having a plurality of driving electrodes in which electrostatic capacitance is formed between an operation face operated by a finger of a user and the finger coming in contact with the operation face, wherein a driving voltage is applied to each driving electrode, and voltage change or current change when the finger approaches the driving electrode to which the driving voltage is applied is detected as an input detection signal, comprising:
a correction electrode that is provided at a position away from the operation face;
a common driving unit that applies a driving voltage to both of the driving electrode and the correction electrode; and
a common detection unit that detects both of a correction detection signal that is the voltage change or the current change when the driving voltage is applied to the correction electrode, and the input detection signal,
wherein the input detection signal is corrected on the basis of the correction detection signal.

2. The electrostatic capacitance-type input device according to claim 1, wherein a driving voltage with the same time length is applied from the driving unit to each driving electrode and the correction electrode.

3. The electrostatic capacitance-type input device according to claim 2, wherein a driving voltage with the same time length is sequentially applied in the same cycle from the driving unit to each driving electrode and the correction electrode.

4. The electrostatic capacitance-type input device according to claim 1, wherein a plurality of driving electrodes and a plurality of detection electrodes at an interval from the driving electrodes are provided on the operation face, a correction detection electrode opposed to the correction electrode is provided, and the detection electrode and the correction detection electrode are connected to each other, and
wherein the input detection signal is obtained from the detection electrode when the driving voltage is applied to the plurality of driving electrodes, and the correction detection signal is obtained from the correction detection electrode when the driving voltage is applied to the correction electrode.

5. The electrostatic capacitance-type input device according to claim 4, wherein electrostatic capacitance formed between one detection electrode and the driving electrode adjacent thereto and electrostatic capacitance between the correction electrode and the correction detection electrode are substantially the same.

6. The electrostatic capacitance-type input device according to claim 4, further comprising a plurality of X electrodes arranged in parallel to each other and a plurality of Y electrodes arranged in parallel to each other in a direction perpendicular to the X electrodes, wherein one side of the X electrodes and the Y electrodes serves as the driving electrode and the other side serves as the detection electrode when the driving voltage is applied, and
wherein the driving voltage is applied to the correction electrode with any one side of the X electrodes and the Y electrodes.

7. The electrostatic capacitance-type input device according to claim 1, wherein a plurality of driving electrodes with the same area are arranged on the operation face, and the correction electrode is formed with the same area as that of the driving electrode, and
wherein the driving voltage is applied from the driving unit to the driving electrode and the correction electrode, an input detection signal is obtained from each driving electrode, and a correction detection signal is obtained from the correction electrode.
